(19) United States
(12) Patent Application Publication
(10) Pub. No.: US 2026/0023144 A1
(43) Pub. Date: Jan. 22, 2026

(54) Method and Apparatus for Reconstructing Images in Magnetic Resonance Tomography

(71) Applicant: Siemens Healthineers AG, Forchheim (DE)

(72) Inventors: Flavio Carinci, Würzburg (DE); Dominik Paul, Bubenreuth (DE)

(73) Assignee: Siemens Healthineers AG, Forchheim (DE)

(21) Appl. No.: 19/271,295

(22) Filed: Jul. 16, 2025

(30) Foreign Application Priority Data
Jul. 17, 2024 (DE) 10 2024 206 721.0

(51) Int. Cl. G01R 33/56; G01R 33/565; G06T 7/00; G06T 11/00

(52) U.S. Cl. CPC G01R 33/5608; G01R 33/5602; G01R 33/56545; G06T 7/0012; G06T 11/006; G06T 11/008; G06T 2207/10088; G06T 2207/30004; G06T 2210/41; G06T 2211/424

(57) ABSTRACT

A method for reconstructing MR tomography images from asymmetrically acquired k-space raw data, with symmetrical and asymmetrical parts, may include reconstructing a phase image from the symmetrical k-space data, applying an iterative k-space reconstruction starting with a base image, and forming a working space via k-space transform. A weighting filter may be applied, assigning zero weight where no raw data exists, lower weight to symmetrical data, and non-zero weight to other data. A complex intermediate image is generated by image space transform of weighted k-space data, phase-corrected with the phase image, and the final result image is obtained as the real part of the phase-corrected intermediate image.

### CROSS REFERENCE TO RELATED APPLICATIONS

This patent application claims priority to German Patent Application No. 102024206721.0, filed Jul. 17, 2024, which is incorporated herein by reference in its entirety.

### BACKGROUND

### Field

The disclosure relates to a method and an apparatus for reconstructing images in magnetic resonance tomography from raw data provided in the form of asymmetrically acquired k-space data, and to a medical technology system in the form of an MRT system and/or a diagnostic system.

### Related Art

In magnetic resonance tomography (MRT) data is first acquired in the so-called k-space and images are reconstructed from this data in a subsequent step, typically by means of Fourier transforms. Data collection takes a comparatively long time in MRT examinations, so that techniques are frequently used which shorten the acquisition time. It should be noted here that in the k-space data the information on the image data is distributed over the entire space, similarly to a hologram. Central k-lines are in this case more important in the reconstruction than k-lines that are further away from the center.

One possibility for reducing the acquisition time is to acquire the k-space asymmetrically. For this, some of the k-lines are acquired symmetrically about a central area of the z-space and some on only one side of this central area. The other side is not acquired (see e.g. FIG. 2). Such an acquisition is also referred to as a “partial Fourier acquisition”. If this is used in phase encoding or in the 3D direction, a reduction in the capture time or in the length of the echo train is achieved. When used in the readout direction (asymmetrical echo) the echo time can be shortened. A partial Fourier acquisition is thus based on the partial capture of the k-space, which is scanned asymmetrically.

In order to reconstruct images from such data, special reconstruction techniques which take this asymmetrical acquisition of k-lines into account are advantageous. Several algorithms are known in the prior art for reconstructing images from an asymmetrically scanned k-space. However, they generally result in stronger blurring or ringing artifacts compared to images obtained from a fully scanned k-space.

Two of the most popular methods for reconstructing images from an asymmetrically scanned k-space are the Homodyne/Margosian reconstruction and Projections Onto Convex Sets (POCS).

The Homodyne/Margosian reconstruction method can be summarized as follows:
1) The uncaptured data is filled with zeros in the k-space (zero fill).
2) The partially captured k-space data is weighted with the aid of an asymmetrical filter W(k) (see e.g. FIG. 3).
3) The resulting k-space is inversely Fourier-transformed, in order to generate an intermediate image K.
4) A low-resolution phase image ϕ is reconstructed from an inverse Fourier transform of the central and symmetrically scanned k-space data.
5) A phase correction is performed by multiplying the intermediate image K by e^{-iϕ}.
6) The final image is obtained as a real part of the phase-corrected intermediate image K, which can be expressed by: S=Re(K·e^{-iϕ}).

Since phase fluctuations normally have a low-frequency pattern, the low-resolution phase image is normally sufficient to achieve an acceptable phase correction.

POCS is an iterative method which starts with an image filled with zeros, and in which the phase of an image reconstructed anew in each iteration is replaced by the low-resolution symmetrical phase image ϕ. This effectively means that a fraction of the signal present in the scanned radio-frequency part of the k-space is displaced to the opposite, unscanned side. The next step is to maintain the data consistency by reinserting the originally measured k-space data (where appropriate filtered). Then the next iteration begins. Thus, at the end of each iteration only the unscanned part of the k-space has changed compared to the beginning. After a given number of iterations or if the change in the k-space between two iterations is below a certain level, the process is terminated.

A disadvantage of Homodyne/Margosian reconstruction is that images reconstructed in this way are typically blurred if the partial Fourier factor (=number of k-space lines captured/number of lines of a fully scanned k-space) is close to 50%.

Images acquired using POCS typically have ringing artifacts, this being a disadvantage of this method.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 illustrates a magnetic resonance tomography system with an apparatus according to an exemplary embodiment of the disclosure.

FIG. 2 is a plot of raw data in k-space according to an exemplary embodiment of the disclosure.

FIG. 3 illustrates a conventional weighting filter.

FIG. 4 is a representation of an image reconstruction method according to an exemplary embodiment of the disclosure.

FIG. 5 a representation of a k-space reconstruction method according to an exemplary embodiment of the disclosure.

FIG. 6 illustrates an asymmetrical step filter according to an exemplary embodiment of the disclosure.

FIG. 7 illustrates an asymmetrical ramp filter according to an exemplary embodiment of the disclosure.

FIG. 8 is a process flow of a method according to an exemplary embodiment of the disclosure.

FIG. 9 is a process flow of a method according to an exemplary embodiment of the disclosure.

The exemplary embodiments of the present disclosure will be described with reference to the accompanying drawings. Elements, features and components that are identical, functionally identical and have the same effect are—insofar as is not stated otherwise-respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to specify a method and an apparatus for reconstructing images in magnetic resonance tomography from raw data provided in the form of asymmetrically acquired k-space data, and a medical technology system in the form of an MRT system and/or a diagnostic system, with which the above-described disadvantages are avoided. It is an object of the disclosure to supply images that are as sharp as possible with as few ringing artifacts as possible. These objects are achieved by a method, an apparatus, and a medical technology system in the form of an MRT system and/or a diagnostic system according to the disclosure.

An inventive method serves to reconstruct images in magnetic resonance tomography from raw data provided in the form of asymmetrically acquired k-space data. The raw data in this case has a symmetrical and an asymmetrical part. The method may comprise the following steps: reconstructing a phase image by means of an image space transform of k-space data of the symmetrical part of the raw data, applying an iterative k-space reconstruction method, starting with a base image reconstructed from the raw data, and applying an image reconstruction method to the working space.

Applying the iterative k-space reconstruction method may comprise the steps:
a1) replacing the phase of the base image by means of the phase image;
b1) forming a working space by performing a k-space transform of the base image into the k-space;
c1) replacing the data of the working space obtained by the base image with the original raw data (where appropriate weighted); and
d1) generating a new base image by applying an image space transform to the working space, and repeating the steps a1 to c1 with a newly generated base image in each case until an abort condition is reached.

Applying the image reconstruction method to the working space may comprise:
a2) providing a weighting filter, which, if the working space corresponds to the raw data, has the weighting zero wherever no raw data has been acquired, and for all other working spaces solely has weightings not equal to zero, and which has a lower weighting in respect of the raw data acquired symmetrically in the k-space than in respect of the raw data acquired asymmetrically in the k-space;
b2) generating a complex intermediate image by means of an image space transform from the k-space data weighted in accordance with the weighting filter;
c2) phase-correcting the intermediate image with the phase image; and
d2) generating a result image as a real part of the phase-corrected intermediate image.

In an exemplary embodiment, the process may advantageously comprise the combination of the Homodyne/Margosian reconstruction and POCS.

Conventionally, methods for reconstructing images or k-space lines may include a Fourier transform, an inverse Fourier transform, a fast Fourier transform or a Fourier-like transform. Since these transforms are well known in the prior art, reference is made below to an “image space transform” if an image is reconstructed from the k-space and to a “k-space transform” if k-space lines are reconstructed from an image.

The method according to the disclosure is particularly advantageous if the acquisition was done in such a way that the k-space is not completely filled and a contiguous part of k-space lines is missing at the edge (less than half the k-space). Then k-space lines exist which are symmetrical to each other in respect of a central axis of the k-space (symmetrical part) as well as k-space lines which have no symmetrical partners since the k-space is not filled there.

The raw data thus has a symmetrical and an asymmetrical part. The symmetrical part may comprise acquired k-space data, which is distributed mirror-symmetrically to a specified central spatial axis of the k-space (in particular to the kRO axis) (thus basically in an area from −k0 to k0).

It should be noted that the raw data can be acquired with further accelerations such as e.g. parallel imaging methods such as GRAPPA, SENSE, CAIPIRINHA, simultaneous multislice or Deep Resolve. Here, every Nth (second, third, . . . ) line of the unsymmetrically scanned k-space is not acquired. If such an additional acceleration takes place, it is treated independently of the inventive method in an image reconstruction, and, in particular, the image space transform and the k-space transform are then designed accordingly. Corresponding transforms are known in the prior art and are not discussed separately here.

The step of reconstructing a (e.g., only coarsely resolved) phase image by means of an image space transform can take place at the start of the method, or else not until the phase image is required. Since the phase image is formed from the symmetrical part of the k-space data and both in the image reconstruction method (basically the Homodyne/Margosian reconstruction) and in the k-space reconstruction method (basically POCS) this data originates directly from the raw data, the phase image can be reconstructed immediately after the acquisition of the raw data and then used for the method.

The phase image is required in both the reconstruction methods of the method, namely the k-space reconstruction method and the image reconstruction method. The special feature of the disclosure is that both reconstruction methods are used. In an exemplary embodiment, the k-space reconstruction method is used first and then the image reconstruction method. Alternatively, or additionally, the image reconstruction method is used as an image space transform within the iterations of the k-space reconstruction method.

The iterative k-space reconstruction method may correspond to POCS in its basic structure. It starts with a predefined base image, in particular a zero image, and passes through multiple iterations.

As regards the base image, it should be noted that the initial base image (prior to the first iteration) is a complex image. If the iterative k-space reconstruction method is performed initially (first pass), then the base image is the result of the image space transform of the raw data (in the k-space). In every other pass, the base image is reconstructed with the current k-space (or working space) in each case.

The k-space reconstruction method may comprise the aforementioned steps a1 to d1, which are passed through many times in multiple iterations. Within an iteration the same operational sequence basically always takes place:

First, the phase of the current base image X (i.e. initially the phase of the zero image and then the phase of the newly generated base image) is replaced by means of the phase image ϕ. This may be done using the formula Re(X)·e^{iϕ} or |X|·e^{iϕ}. Thus the real part or the absolute value of the base image X is replaced with a complex exponential function with the phase image ϕ as an exponent in the complex space. The exponential function corresponds to cos (ϕ)+i sin (ϕ), i.e. a rotation in the complex plane about the angle ϕ. The calculation may be done pixel by pixel, wherein each pixel of the base image is offset with the corresponding pixel of the phase image.

From this modified base image, a working space is now formed by means of a k-space transform and raw data is inserted into this working space, so that it overwrites the k-space data of the working space. Thus, what changes after each iteration is basically the k-space data in the area of the k-space which is not present in the raw data. However, it should be noted here that the raw data too is not necessarily inserted identically into the working space in every iteration. It may be weighted in order to compensate for the additional influence of the “new” k-space data.

Based on this (new) working space a new base image is then reconstructed by using an image space transform and the next iteration begins. In an exemplary embodiment, this image space transform can be the image reconstruction method.

As from any point in time, the changes in the working space are marginal compared to the working space of the preceding iteration. The k-space reconstruction method can then be aborted. The abort condition may be reached if a measure for a difference between temporally consecutive working spaces is undershot or simply after a fixed number of iterations.

Thus, the phase of each pixel of an initial complex image is replaced by a local ϕ (pixel of the phase image), a working space is created therefrom, k-lines are replaced there with the raw data, a new base image is reconstructed therefrom, this is in turn phase-replaced with ϕ, a new working space is created and so on. In the end, the last working space is available as k-space for an image reconstruction.

The procedure in the image reconstruction method is similar to that in the Homodyne/Margosian reconstruction. However, the difference is the filter that is used. Regardless of the specific application (in accordance with or in the k-space reconstruction method), the entire k-space is usually used for the reconstruction of the result image.

This is due to the asymmetrical filter used. Only if the working space corresponds to the raw data does this not apply, but rather the weighting filter also used in the Homodyne/Margosian reconstruction with a zero weighting for the areas outside the raw data acquired. However, this case only occurs on the first pass of the k-space reconstruction method. In all other cases (application of the image reconstruction method after the first pass of the k-space reconstruction method), the weighting filter only has weightings not equal to zero, such as weightings greater than zero.

In this case the weighting filter has a lower weighting in respect of the raw data acquired symmetrically in the k-space than in respect of raw data acquired asymmetrically in the k-space. It should be noted that this refers to the raw data. If the working space in the other area which is empty in the raw data contains k-lines with values, the weighting filter has a weighting there not equal to zero, in particular greater than zero. For standardization, the sum of the weightings of the asymmetrical part of the raw data and its counterparts may be essentially twice the weighting of the symmetrical part.

The form of the filter can be selected prior to the method. In an exemplary embodiment, step filters may be used that include a step for the part of the k-space which is not contained in the raw data (“missing part”), an intermediate step for the symmetrical part, and a step for the asymmetrical part. However, a smoothed (or apodized) form of the weighting filter can also be used. Instead of the intermediate step, a ramp can be used in the central (symmetrical) part of the k-space.

By means of an image space transform, a complex intermediate image is then generated from the k-space data of the working space weighted in accordance with the weighting filter. A phase correction of the intermediate image with the phase image is then carried out. Lastly, a result image is generated as a real part of the phase-corrected intermediate image.

As already stated, if the transform is carried out on a working space which corresponds to the raw data, this is the well-known Homodyne/Margosian reconstruction. In all other cases it is not, since another (asymmetrical) weighting filter is used.

An inventive apparatus serves to reconstruct images in magnetic resonance tomography from raw data provided in the form of asymmetrically acquired k-space data, wherein the raw data has a symmetrical and an asymmetrical part. The apparatus may comprise the following components: a phase image unit (phase image reconstructor) configured to reconstruct a phase image by means of an image space transform of k-space data of the symmetrical part of the raw data, a k-space reconstruction unit (k-space reconstructor) configured to use an iterative k-space reconstruction method, and an image reconstruction unit (image reconstructor) configured to apply an image reconstruction method to the working space.

The k-space reconstruction unit may be configured to use an iterative k-space reconstruction method, starting with a base image reconstructed from the raw data and comprising the steps:
a1) replacing the phase of the base image by means of the phase image,
b1) forming a working space by performing a k-space transform of the base image into the k-space,
c1) replacing the data of the working space obtained by the base image with the original raw data, and
d1) generating a new base image by applying an inverse Fourier transform to the working space, and repeating the steps a1 to c1 until an abort condition is reached with the new base image.

The image reconstruction unit may apply an image reconstruction method to the working space, comprising the steps:
a2) providing a weighting filter, which, if the working space corresponds to the raw data, has the weighting zero wherever no raw data has been acquired, and for all other working spaces solely has weightings not equal to zero, and which has a lower weighting in respect of the raw data acquired symmetrically in the k-space than in respect of the raw data acquired asymmetrically in the k-space,
b2) generating a complex intermediate image by means of an image space transform from the k-space data weighted in accordance with the weighting filter,
c2) phase-correcting the intermediate image with the phase image, and
d2) generating a result image as a real part of the phase-corrected intermediate image.

The function of the components of the apparatus has already been described above. The apparatus may be configured to execute an inventive method.

An inventive medical technology system is present in the form of an MRT system and/or a diagnostic system and may comprise an apparatus in accordance with the disclosure or is configured to perform the method in accordance with the disclosure.

The disclosure can be implemented in the form of a computing unit (computer) with suitable software. For this, the computing unit can for example have one or more interworking microprocessors or the like. It can be implemented in the form of suitable software program parts in the computing unit. A largely software-based implementation has the advantage that even previously used computing units can easily be retrofitted by a software or firmware update in order to work in the inventive manner. In this respect, the object is also achieved by a corresponding computer program product with a computer program which can be loaded directly into a memory facility of a computing unit, with program sections to execute all steps of the inventive method if the program is executed in the computing unit. In addition to the computer program, such a computer program product can include additional components such as e.g. documentation and/or additional components, including hardware components, such as e.g. hardware keys (dongles, etc.) for the use of the software.

A computer-readable medium, for example a memory stick, a hard disk or another portable or permanently installed data carrier, on which the program sections of the computer program that can be read and executed by a computing unit are stored, can be used for transport to the computing unit and/or for storage on or in the computing unit.

Further, particularly advantageous embodiments and developments of the disclosure arise from the dependent claims and the following description, wherein the claims in one claim category can also be developed analogously to the claims and parts of the description to form another claim category and in particular individual features of different exemplary embodiments or variants can also be combined to form new exemplary embodiments or variants.

In an exemplary embodiment of the method, the k-space reconstruction method is first applied to the raw data and the image reconstruction method is carried out with k-space data of the working space thereby obtained. The working space which was created in the last iteration of the k-space reconstruction method may be used for this. In this respect, the k-space data obtained by the k-space reconstruction method may be weighted the least in connection with the image reconstruction method.

In short: In this and the form of embodiment described below, the image reconstruction method is applied according to the k-space reconstruction method and works with its (last) working space. This has the advantage that the image reconstruction can be performed with a (fully) filled k-space. By replacing the data missing from the raw data, the reconstructed images become sharper than in a simple Homodyne/Margosian reconstruction and have fewer ringing artifacts than in the simple application of POCS.

In an exemplary embodiment, the method may comprise the steps: generating a (final) working space by multiple iterations of the k-space reconstruction method; and applying the image reconstruction method to the working space, where:
a2) an asymmetrical weighting filter is provided, which weights the reconstructed k-space data of the working space less than the raw data contained in the working space,
b2) the complex intermediate image is created by means of an image space transform from the k-space data weighted in accordance with this weighting filter,
c2) a phase correction of this intermediate image is carried out with the phase image, and
d2) the result image is generated as a real part of this phase-corrected intermediate image.

In an exemplary embodiment of the method, the image reconstruction method is used within at least one of the iterations of the k-space reconstruction method, such as within all iterations, wherein in an iteration the respective result image of the image reconstruction method is used as a base image.

In short: In this and the form of embodiment described below, the image reconstruction method is used as an image space transform within the k-space reconstruction method and works with its working space (created previously in each case). This has the advantage that the iterations can be performed with a more powerful image reconstruction. At the end, the last generated result image should then be used as the output. This makes the reconstructed images sharper than in a simple Homodyne/Margosian reconstruction and has fewer ringing artifacts than in the simple application of POCS.

The method may comprise the steps:
creating a working space in the form of a k-space filled with the raw data, in which the value zero is assigned to the areas of the working space which do not contain any raw data, and
generating a first base image by applying the image reconstruction method to the working space, wherein the result image of the image reconstruction method is the base image and wherein in the first pass of the k-space reconstruction method a first weighting filter is used, which has a weighting of zero wherever in the working space the k-space data has the value zero.

In an exemplary embodiment, the method comprises:
a1) replacing the phase of this base image by means of the phase image,
b1) forming a working space by performing a k-space transform of this phase-changed base image into the k-space,
c1) replacing the data of the working space obtained by this base image with the original raw data, and
d1) generating a new base image by renewed application of the image reconstruction method to the working space obtained by step c1, wherein the result image of the image reconstruction method is the new base image and wherein a number of further weighting filters is used, such as a single weighting filter, which, wherever in the working space the k-space data does not correspond to the raw data, has a weighting greater than zero, but less than the weighting of the other areas of the working space, and repeating the steps a1 to c1 until an abort condition is reached with the new base image.

In an exemplary embodiment of the method, in the image reconstruction method the phase correction of the intermediate image K with the phase image ϕ is carried out by multiplying the image K by the phase image ϕ using the calculation K·e^{-iϕ}. In an exemplary embodiment, the result image S may be generated using the formula S=Re (K·e^{-iϕ}) or S=|K·e^{-iϕ}).

In an exemplary embodiment of the method, in the k-space reconstruction method the phase of the base image X is replaced by means of the phase image ϕ using the calculation Re(X)·e^{iϕ} or |X| ·e^{iϕ}.

In an exemplary embodiment of the method, the weighting filter for raw data acquired symmetrically in the k-space has a weighting of W2, for raw data acquired asymmetrically in the k-space the weighting W3, and for areas without any acquired raw data the weighting W1. In an exemplary embodiment, if reconstructed k-space data is present for areas without any acquired raw data, the following applies: 0<W1<W2<W3 or W3<W2<W1<0. In an exemplary embodiment, 2W2=W1+W3 applies, so that the asymmetrical data (weighted with W1 and W3) is weighted in accordance with the symmetrical data (W2).

In an exemplary embodiment, the weighting filter may be:
a step filter, in which the weightings W1, W2, and W3 are constant;
W2 a continuous and monotonically ascending function between W1 and W3, such as where the weightings W1 and W3 are constant;
at least one of the weightings W1, W2, W3 is a non-constant function; and/or
W1 and/or W3 drop toward the outer boundaries of the k-space.

In accordance with an exemplary embodiment of the method, the same phase image is used both for the image reconstruction method and for the k-space reconstruction method.

In an exemplary embodiment, AI-based methods (AI: “Artificial Intelligence”) may be used. Artificial intelligence is based on the principle of machine-based learning, and is generally performed with an adaptive algorithm which has been trained accordingly. The term “machine learning” is frequently used for machine-based learning, the principle of “deep learning” also being included here. These AI-based methods are particularly suitable for transforms into the image space or into the k-space.

In an exemplary embodiment, components of the disclosure are available as a “cloud service.” Such a cloud service is used to process data, in particular by means of artificial intelligence, but can also be a service based on conventional algorithms or a service in which a human evaluation takes place in the background. Generally speaking, a cloud service (hereinafter also referred to as the “cloud” for short) is an IT infrastructure in which e.g. storage space or computing power and/or application software is made available via a network. Communication between the user and the cloud takes place by means of data interfaces and/or data transmission protocols. In an exemplary embodiment, the cloud service provides both computing power and application software.

In an exemplary embodiment, data which is obtained in connection with the disclosure is provided to the cloud service via the network. This may comprise a computing system which generally does not include the user's local computer. The method can be implemented in a network by means of a command constellation. The data calculated in the cloud is later sent back to the user's local computer via the network.

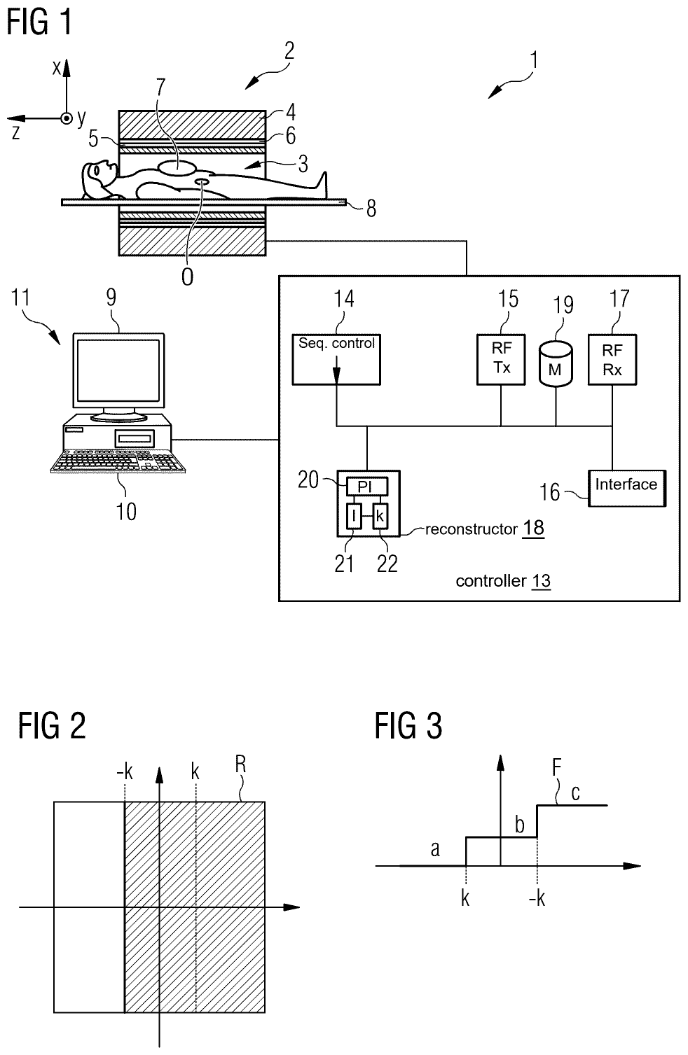

FIG. 1 shows a magnetic resonance tomography system 1 according to one or more exemplary embodiments of the disclosure. The system 1 may comprise a magnetic resonance (MR) scanner 2 with an examination space 3 or patient tunnel (which is regarded here as the acquisition area 3), in which a patient or test subject in whose body the actual object under examination O is located is positioned on a couch 8.

The magnetic resonance scanner 2 may be fitted with a main field magnet system 4 and a gradient system 6, as well as an RF transmitting antenna system 5 and an RF receiving antenna system 7. In the exemplary embodiment shown the RF transmitting antenna system 5 is a whole-body coil permanently incorporated in the magnetic resonance scanner 2, whereas the RF receiving antenna system 7 consists of local coils to be arranged on the patient or test subject (here symbolized only by a single local coil). In principle, however, the whole-body coil can also be used as an RF receiving antenna system and the local coils as an RF transmitting antenna system, provided that these coils can each be switched to different modes of operation. The main field magnet system 4 is here designed in the normal way so that it generates a main magnetic field in the longitudinal direction of the patient, i.e. along the longitudinal axis of the magnetic resonance scanner 2, which runs in the z-direction. The gradient system 6 normally includes individually controllable gradient coils in order to be able to switch gradients independently of each other in the x, y or z direction.

The magnetic resonance tomography system shown here is a whole-body installation with a patient tunnel, into which a patient can be introduced completely. However, in principle the disclosure can also be used on other magnetic resonance tomography systems, e.g. with a C-shaped housing open at the sides. The only important thing is that corresponding acquisitions of the object under examination O can be made.

The magnetic resonance tomography system 1 may further comprise a central control facility (controller) 13, which may be configured to control the MR system 1. In an exemplary embodiment, the controller 13 includes processing circuitry that is configured to perform one or more operations and/or functions of the controller 13. Additionally, or alternatively, one or more components of the controller 13 (e.g., 14, 15, 16, 17, 18, and/or 19) may include processing circuitry that is configured to perform one or more operations and/or functions of the respective component(s).

The controller 13 may include a sequence control unit (controller) 14 configured to control the operational sequence of radio-frequency pulses (RF pulses) and of gradient pulses as a function of a selected pulse sequence or an operational sequence of multiple pulse sequences for the acquisition of multiple slices in the acquisition area within a scanning session. Such a pulse sequence can, for example, be specified and parameterized within a scanning or control protocol. Various control protocols for different scans or scanning sessions may be stored in a memory 19 and can be selected by an operator (and if need be where appropriate modified) and then used to perform the scan.

Based on selected pulse sequences or the positioning of the aforementioned RF receiving antenna system 7, the field of examination can be determined.

To output the individual RF pulses of a pulse sequence, the controller 13 may include a radio-frequency transmitting facility (RF transmitter) 15, which generates the RF pulses, amplifies them, and feeds them into the RF transmitting antenna system 5 via a suitable interface (not shown in detail). To control the gradient coils of the gradient system 6 in order to switch the gradient pulses appropriately according to the specified pulse sequence, the controller 13 may include a gradient system interface 16. This gradient system interface 16 could be used to apply the diffusion gradient pulses and spoiler gradient pulses. The sequence control unit 14 communicates in an appropriate manner, e.g. by emitting sequence control data, with the radio-frequency transmitting facility 15 and the gradient system interface 16 for the execution of the pulse sequence.

The control facility (controller) 13 may additionally include a radio-frequency (RF) receiving facility (RF receiver) 17 (likewise communicating with the sequence control unit 14 in an appropriate manner), in order to receive magnetic resonance signals within the readout windows specified by the pulse sequence in a coordinated manner by means of the RF receiving antenna system 7 and thus to acquire the raw data R.

A reconstruction unit (reconstructor) 18 here takes over the acquired raw data R and reconstructs magnetic resonance image data therefrom. This reconstruction may be generally carried out on the basis of parameters which can be specified in the respective scanning or control protocol. This image data can then be stored in memory 19 and/or provided as an output signal of the controller 13. In an exemplary embodiment, the controller 13 may communicate with one or more computing devices 11, which may be used provide information to the controller 13, output information provided from the controller 13, and/or otherwise control and/or configure the controller 13. The computing device (e.g., computer) 11 may include an output interface 9, such as a display and/or speaker; and/or input interface 10, such as a keyboard, touchscreen, mouse, etc. The computing device 11 may include processing circuitry configured to perform the functions/operations of the computing device 11.

The reconstruction unit 18 may be configured as an inventive apparatus 18. Raw data R, in the form of asymmetrically acquired k-space data, can thus be optimally reconstructed into images, wherein the raw data R has a symmetrical and an asymmetrical part. The apparatus 18 may comprise a phase image unit 20, a k-space reconstruction unit 22 and an image reconstruction unit 21. The functions of these units and their interaction are explained in greater detail below.

How in detail suitable raw data R can be acquired by irradiating RF pulses and switching gradient pulses and how MR images or parameter maps can be reconstructed therefrom is known in principle to the person skilled in the art, and further discussion is omitted for brevity. Similarly, how suitable raw data R can be acquired by irradiating RF pulses and generating gradient fields, and how magnetic resonance tomography images can be reconstructed therefrom, is likewise known to the person skilled in the art, and further discussion is omitted for brevity.

FIG. 2 outlines raw data R in the k-space. This was obtained by an asymmetrical acquisition, in which the white part of the k-space shown here on the left was not acquired, and the right, hatched part represents the raw data R. The raw data R has a symmetrical part between −k and k, which is mirror-symmetrical to the vertical axis (arrow), and an asymmetrical part (beyond k, i.e. to the right of the dashed line). Zero values for the k-lines can be inserted in the white part.

This representation is intended to outline the nature of the raw data R with which the inventive method advantageously works.

FIG. 3 outlines a weighting filter F in accordance with the prior art, as is typically used for a Homodyne/Margosian reconstruction of the raw data R from FIG. 2. Where no raw data R is present in FIG. 2, the weighting filter F has the weighting zero (weighting zone a, left), for the symmetrical part of the raw data R a higher weighting (weighting zone b, center, e.g. a weighting of 1), and for the asymmetrical part of the raw data R an even higher weighting (weighting zone c, right, e.g. a weighting of 2).

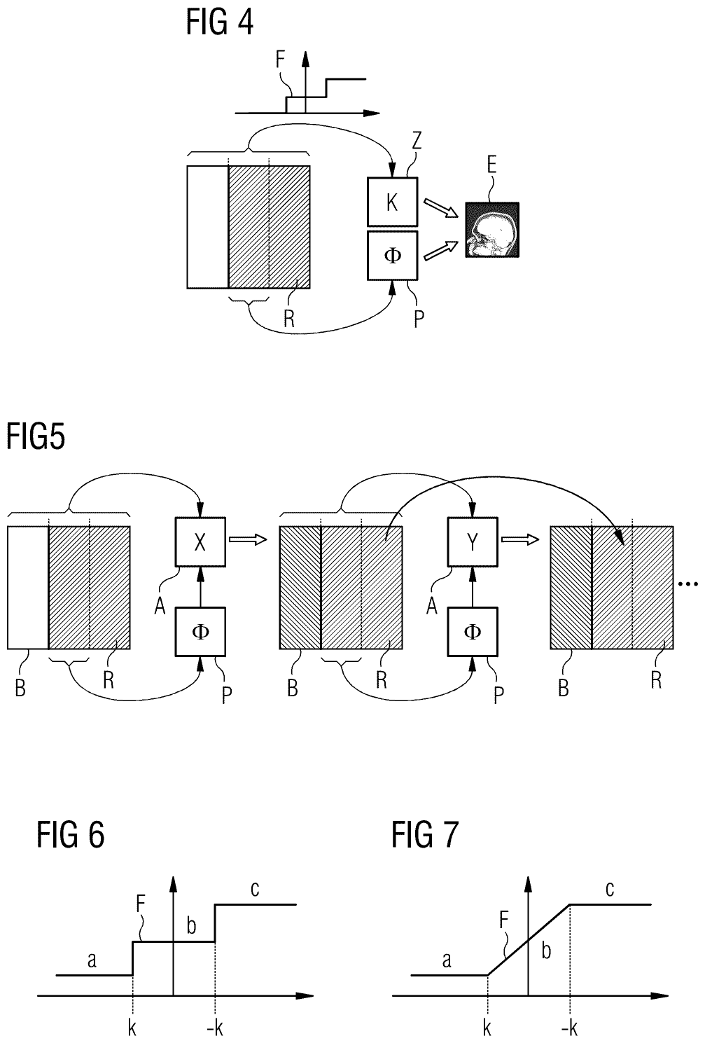

FIG. 4 shows a representation of an image reconstruction method as is used in the disclosure. In the case shown this is a Homodyne/Margosian reconstruction, which is applied to the raw data R according to FIG. 2 with a weighting filter F according to FIG. 3. This would be the case for example within the first pass of the k-space reconstruction method. For all other applications of the image reconstruction method within the inventive method, the k-space is completely filled with data (i.e. no white area is present, but e.g. as indicated on the right in FIG. 5) and a weighting filter F is used, which has weightings greater than or less than zero everywhere (see e.g. FIGS. 6 and 7).

As regards the weighting filter F, it can be said that if the working space B corresponds to the raw data R, it has the weighting zero wherever no raw data R has been acquired, and for all other working spaces B it solely has weightings not equal to zero. In respect of the raw data R acquired symmetrically in the k-space, the weighting filter F has a lower weighting than in respect of the raw data R acquired asymmetrically in the k-space. For reconstructed data, the weighting is even lower.

A complex intermediate image Z is then created by means of an image space transform from the k-space data weighted in accordance with the weighting filter F (upper arrow, image “K”). A phase image P is generated from the symmetrical part (lower image ϕ). How this is done is known in the prior art and corresponds to the relevant steps of the Homodyne/Margosian reconstruction.

A phase correction of the intermediate image Z (designated “K”) now takes place with the phase image P (designated “ϕ”) and a result image E is generated. This too corresponds to the relevant steps of the Homodyne/Margosian reconstruction. In this example, the result image E designated “S” is obtained in accordance with the formula S=Re(K·e^{-iϕ}).

FIG. 5 shows a representation of the k-space reconstruction method as is used in the disclosure. It resembles an iterative reconstruction in accordance with POCS. The first pass is shown on the far left. A base image A is reconstructed from the raw data R which forms the (first) working space B and is here in each case designated “X”. The base image A is here present as a real part of a complex image and its phase is replaced by means of the phase image P (here provided with “ϕ”) using the formula Re(X)·e^{iϕ}.

From the resulting base image A, a working space B is then again generated by a k-space transform and in this the data of the working space B obtained by the base image A (hatched diagonally to the right) is replaced with the original raw data R (hatched diagonally to the left). The raw data R can be inserted weighted as a function of the fill of the other part.

A new base image A is now generated by applying an image space transform to the working space B (center). These steps are repeated progressively to the right until an abort condition.

FIG. 6 shows an example of an asymmetrical step filter which can be used in the disclosure. This weighting filter F resembles the one in FIG. 3, with the difference that the step function is displaced upward, so that only positive weightings are present and no weighting factor is zero.

FIG. 7 shows an example of an asymmetrical ramp filter which can be used in the disclosure. This weighting filter F resembles the one in FIG. 6, with the difference that the center step is here a ramp. This ramp should be rotationally symmetrical to the intersection with the vertical axis.

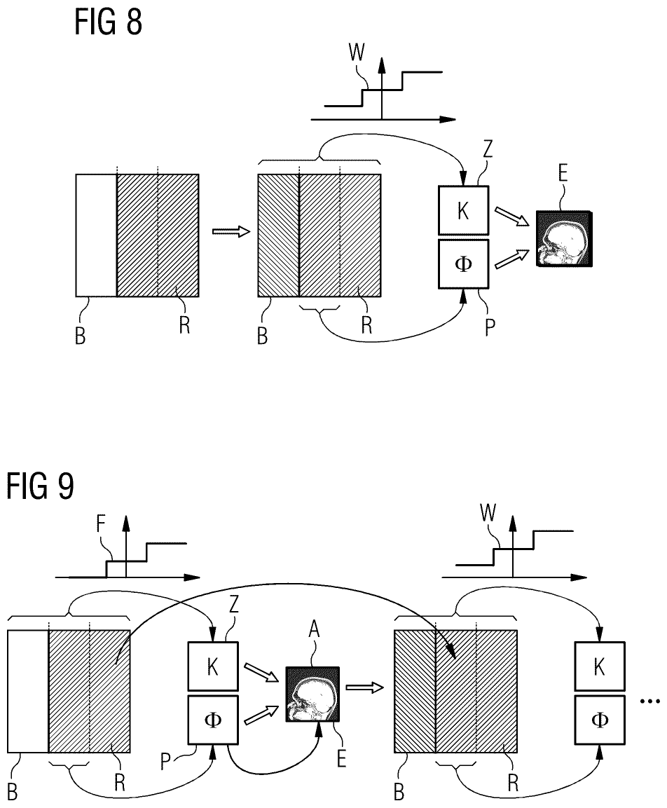

FIG. 8 shows a representation of the inventive method according to an exemplary embodiment of the disclosure. The raw data R (k-space) is again used as the starting point. A working space B is now generated from this raw data R in accordance with a method according to FIG. 5. An image reconstruction method similar to FIG. 4 is applied to this working space B, with the difference that instead of a filter according to FIG. 3, a filter according to FIG. 6 is used. The result data E has a high degree of sharpness with only very few ringing artifacts.

FIG. 9 shows a representation of the inventive method according to an exemplary embodiment of the disclosure. Starting from the raw data R, an image reconstruction method according to FIG. 4 is performed, in order to obtain a first base image A (result image E of the image reconstruction method), and then the method according to FIG. 5, wherein an image reconstruction method similar to FIG. 4 is used as an image space transform of this method in each iteration, with the difference that instead of a filter according to FIG. 3 a filter according to FIG. 6 is used. The last result data E has a high degree of sharpness with only very few ringing artifacts.

In conclusion it is once again noted that the disclosure described in detail above relates solely to exemplary embodiments that can be modified by the person skilled in the art in a variety of ways, without departing from the scope of the disclosure. Further, the use of the indefinite article “a” or “an” does not rule out that the features in question may also be present multiple times. Likewise, terms such as “unit” do not rule out that the components in question consist of multiple interacting subcomponents which if appropriate may also be distributed spatially. The term “a number” should be understood as “at least one”. Independent of the grammatical term usage, individuals with male, female or other gender identities are included within the term.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for reconstructing images in magnetic resonance tomography from raw data provided in the form of asymmetrically acquired k-space data, the raw data having a symmetrical part and an asymmetrical part, the method comprising:
reconstructing a phase image based on an image space transform of k-space data of the symmetrical part of the raw data;
performing an iterative k-space reconstruction method, starting with a base image reconstructed from the raw data and comprising:
a1) replacing the phase of the base image by means of the phase image,
b1) forming a working space by performing a k-space transform of the base image into the k-space,
c1) replacing the data of the working space obtained by the base image with the original raw data, and
d1) generating a new base image by applying an image space transform to the working space, and repeating a1) to c1) with a newly generated base image in each iteration until an abort condition is reached; and
applying an image reconstruction method to the working space, comprising:
a2) providing a weighting filter, wherein: in response to the working space corresponding to the raw data, includes a zero weighting wherever raw data has not been acquired, and, for all other working spaces, solely includes non-zero weightings, and wherein the weighting filter includes a lower weighting for the raw data acquired symmetrically in k-space than for the raw data acquired asymmetrically in k-space,
b2) generating a complex intermediate image by means of an image space transform from the k-space data weighted in accordance with the weighting filter,
c2) phase-correcting the intermediate image with the phase image, and
d2) generating a result image as a real part of the phase-corrected intermediate image.

2. The method as claimed in claim 1, wherein the k-space reconstruction method is first applied to the raw data and the image reconstruction method is performed with k-space data of the working space thereby obtained.

3. The method as claimed in claim 2, wherein the image reconstruction method is performed with k-space data of the working space obtained in the last iteration, and wherein the k-space data obtained by the k-space reconstruction method is weighted the least in connection with the image reconstruction method.

4. The method as claimed in claim 2, comprising:
generating a working space by multiple iterations of the k-space reconstruction method; and
applying the image reconstruction method to the working space, wherein:
a2) an asymmetrical weighting filter is provided, which weights the reconstructed k-space data of the working space less than the raw data contained in the working space,
b2) the complex intermediate image is created based on an image space transform from the k-space data weighted in accordance with this weighting filter,
c2) a phase correction of the complex intermediate image with the phase image is performed, and
d2) the result image is generated as a real part of the phase-corrected intermediate image.

5. The method as claimed in claim 1, wherein the image reconstruction method is used within at least one of the iterations of the k-space reconstruction method, and wherein the respective result image of the image reconstruction method is used in an iteration as a base image.

6. The method as claimed in claim 5, comprising:
creating a working space with a k-space filled with the raw data, in which a zero value is assigned to areas of the working space containing no raw data;
generating a first base image by applying the image reconstruction method to the working space, wherein the result image of the image reconstruction method is the base image and wherein in the first pass of the k-space reconstruction method a first weighting filter is used, which has a zero weighting wherever in the working space the k-space data has the value zero,
a1) replacing the phase of the first base image based on the phase image;
b1) forming a working space by performing a k-space transform of the phase-changed base image into k-space;
c1) replacing the data of the working space obtained by the first base image with the original raw data; and
d1) generating a new base image by renewed application of the image reconstruction method to the working space obtained by step c1, wherein the result image of the image reconstruction method is the new base image and wherein a number of further weighting filters is used, which, wherever in the working space the k-space data does not correspond to the raw data, has a weighting greater than zero but less than the weighting of the other areas of the working space and repeating the steps a1 to c1 until an abort condition is reached with the new base image.

7. The method as claimed in claim 1, wherein, in the image reconstruction method, the phase correction of the intermediate image K with the phase image ϕ takes place by multiplying the image K by the phase image ϕ using the calculation K·e^{-iϕ}, wherein the result image S is generated based on S=Re(K·e^{-iϕ}) or S=|K·e^{-iϕ}|.

8. The method as claimed in claim 1, wherein, in the k-space reconstruction method, the replacement of the phase of the base image X by the phase image ø is performed based on Re(X)·e^{iϕ} or |X|·e^{iϕ}.

9. The method as claimed in claim 1, wherein:
the weighting filter for:
raw data acquired symmetrically in k-space has a weighting of W2,
raw data acquired asymmetrically in the k-space has a weighting W3, and
areas without any acquired raw data has a weighting W1; and
in response to areas without any acquired raw data reconstructed k-space data being present, the weightings have the following relationship: 0<W1<W2<W3, or W3<W2<W1<0.

10. The method as claimed in claim 9, wherein:
the weighting filter is a step filter in which the weightings W1, W2, and W3 are constant;
W2 is a continuous and monotonically ascending function between W1 and W3, the weightings W1 and W3 being constant;
at least one of the weightings W1, W2, W3 is a non-constant function; or
W1 and/or W3 drop towards outer boundaries of k-space.

11. The method as claimed in claim 1, wherein a same phase image is used both for the image reconstruction method and for the k-space reconstruction method.

12. An apparatus comprising:
one or more processors; and
memory storing instructions that, when executed by the one or more processors, cause the apparatus to perform the method of claim 1.

13. One or more non-transitory media storing instructions that, when executed by one or more processors, cause the one or more processors to perform the method of claim 1.

14. An apparatus for reconstructing images in magnetic resonance tomography from raw data provided in the form of asymmetrically acquired k-space data, the raw data having a symmetrical part and an asymmetrical part, the apparatus comprising:
a phase image reconstructor configured to reconstruct a phase image based on an image space transform of k-space data of the symmetrical part of the raw data;
a k-space reconstructor configured to use an iterative k-space reconstruction method, starting with a base image reconstructed from the raw data and comprising:
a1) replacing the phase of the base image based on the phase image,
b1) forming a working space by performing a k-space transform of the base image into the k-space,
c1) replacing the data of the working space obtained by the base image with the original raw data, and
d1) generating a new base image by applying an image space transform to the working space, and repeating a1) to c1) until an abort condition is reached with the new base image; and
an image reconstructor configured to apply an image reconstruction method to the working space, comprising:
a2) providing a weighting filter, wherein: in response to the working space corresponding to the raw data, includes a zero weighting wherever raw data has not been acquired, and, for all other working spaces, solely includes non-zero weightings, and wherein the weighting filter includes a lower weighting for the raw data acquired symmetrically in k-space than for the raw data acquired asymmetrically in k-space,
b2) generating a complex intermediate image by means of an image space transform from the k-space data weighted in accordance with the weighting filter,
c2) phase-correcting the intermediate image with the phase image, and
d2) generating a result image as a real part of the phase-corrected intermediate image.

15. A magnetic resonance tomography system comprising the apparatus as claimed in claim 14.
